(19) United States
(12) Patent Application Publication
(10) Pub. No.: US 2025/0338744 A1
(43) Pub. Date: Oct. 30, 2025

(54) DISPLAY AND METHOD OF MANUFACTURING SAME

(71) Applicant: Samsung Electronics Co., Ltd., Suwon-si (KR)

(72) Inventors: Jinwoo JUNG, Suwon-si (KR); Seongyong KIM, Suwon-si (KR); Keon KUK, Suwon-si (KR); Ilju MUN, Suwon-si (KR)

(21) Appl. No.: 19/232,873

(22) Filed: Jun. 10, 2025

Related U.S. Application Data
(63) Continuation of application No. PCT/KR2025/005810, filed on Apr. 29, 2025.

(30) Foreign Application Priority Data
Apr. 29, 2024 (KR) 10-2024-0056562
May 14, 2024 (KR) 10-2024-0063318

(51) Int. Cl. H10K 59/35; H10H 29/34; H10H 29/37; H10H 29/85; H10K 59/122; H10K 59/38

(52) U.S. Cl. CPC H10K 59/353; H10H 29/345; H10H 29/37; H10H 29/8517; H10K 59/122; H10K 59/352; H10K 59/38

(57) ABSTRACT

A display includes: multiple light sources, a partition defining multiple pixel areas corresponding to the multiple light sources, respectively, a color conversion member disposed in some of the multiple pixel areas, a transparent member disposed in another some of the multiple pixel areas; a light-blocking member including multiple open areas corresponding to the multiple pixel areas, respectively, and multiple color filters placed in the multiple open areas, respectively. The multiple color filters may include a first color filter having a first size, and multiple second color filters each having a second size larger than the first size in a plan view. The first color filter overlaps the transparent member in the plan view, and the multiple second color filters overlap the color conversion member in the plan view.

### TECHNICAL FIELD

Embodiments of the disclosure relate to a display and a method of manufacturing the same.

### BACKGROUND ART

Displays function as a key interface supporting interaction between an electronic device and a user, and technologies for providing displays with more advanced performance are being proposed. For example, a display structure capable of expressing pixels with excellent color purity and color reproducibility by converting the color of light provided from a light source using quantum dots is being proposed.

### DISCLOSURE

### Technical Solution

A display according to an embodiment of the disclosure may include multiple light sources, a partition defining multiple pixel areas corresponding to the multiple light sources, respectively, a color conversion member disposed in at least some of the multiple pixel areas, a light-blocking member including multiple open areas corresponding to the multiple pixel areas, respectively, and multiple color filters placed in the multiple open areas, respectively.

According to an embodiment of the disclosure, the multiple color filters may include a first color filter having a first size, and multiple second color filters having a second size larger than the first size.

According to an embodiment of the disclosure, a first center of a first color filter among the multiple color filters may be positioned on a first line in a first direction, and a second center of each of the multiple second color filters among the multiple color filters may be positioned on a second line in the first direction, which is different from the first line.

A method of manufacturing a display according to an embodiment of the disclosure may include placing a light-blocking member including multiple open areas on a first substrate, placing multiple color filters in the multiple open areas, respectively, placing a partition defining multiple pixel areas on the light-blocking member, placing a color conversion member in at least some of the multiple pixel areas, and placing a second substrate, on which multiple light sources respectively corresponding to the multiple pixel areas are placed.

According to an embodiment of the disclosure, the placing of the multiple color filters may include placing a first color filter having a first size and multiple second color filters having a second size larger than the first size.

### Advantageous Effects

A game apparatus having the construction according to at least one embodiment of the present disclosure as described above can˜

### Description of Drawings

FIG. 1 is a block diagram illustrating an electronic device 101 in a network environment 100 according to an embodiment.

FIG. 2 is a block diagram illustrating the display device according to an embodiment.

FIG. 3 is a plan view illustrating multiple pixels of a display according to an embodiment.

FIG. 4A is a view illustrating a method of manufacturing a display according to an embodiment.

FIG. 4B is a view illustrating a process of manufacturing the display according to an embodiment.

FIG. 5 is a view illustrating a process of printing a color conversion member according to an embodiment.

FIG. 6 is a plan view illustrating a portion of a display according to an embodiment.

FIG. 7 is a plan view illustrating the second pixel area and the third pixel area of a portion of the display according to an embodiment.

FIG. 8 is a view illustrating cross-sections of a portion of a display according to one embodiment in various directions.

FIG. 9 is a view illustrating a cross-section of a portion of a display according to another embodiment in one direction.

FIG. 10 is a plan view illustrating a process of printing a transparent member according to an embodiment.

FIG. 11 is a view illustrating cross-sections of portions of a display according to an embodiment in one direction.

In connection with the description of the drawings, the same or similar components may be denoted by the same or similar reference numerals.

### MODE FOR INVENTION

Hereinafter, various embodiments of the present disclosure are described with reference to the accompanying drawings, but which is not intended to limit the present disclosure to any particular embodiment and is to be understood to include various modifications, equivalents, and/or alternatives of the embodiments of the present disclosure.

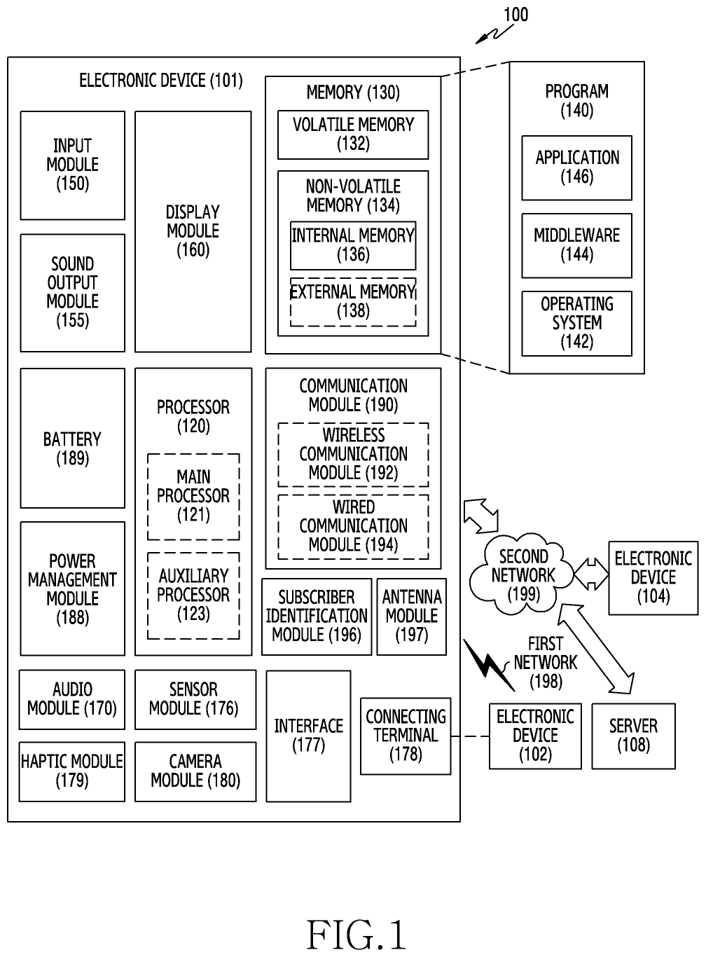

FIG. 1 is a block diagram illustrating an electronic device in a network environment according to an embodiment.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

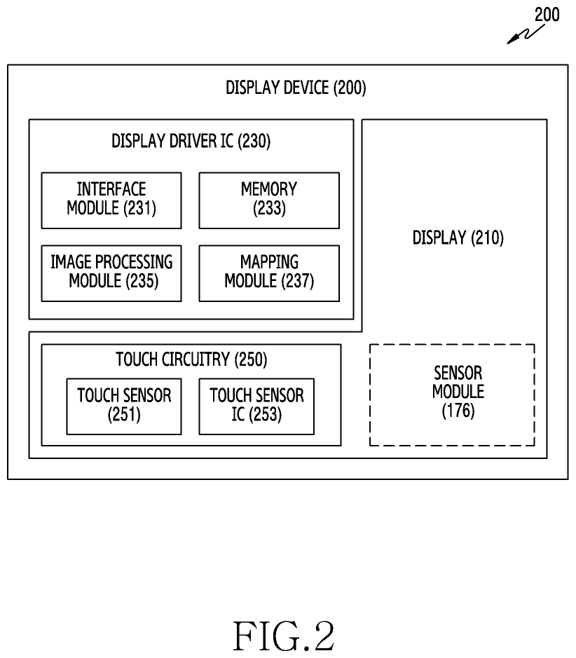

FIG. 2 is a block diagram illustrating the display device according to an embodiment.

Referring to FIG. 2, the display device 200 (for example, the display module 160 of FIG. 1) may include a display 210 and a display driver integrated circuit (DDI) 230 to control the display 210. The DDI 230 may include an interface module 231, memory 233 (e.g., buffer memory), an image processing module 235, or a mapping module 237. The DDI 230 may receive image information that contains image data or an image control signal corresponding to a command to control the image data from another component of the electronic device 101 via the interface module 231. For example, according to an embodiment, the image information may be received from the processor 120 (e.g., the main processor 121 (e.g., an application processor)) or the auxiliary processor 123 (e.g., a graphics processing unit) operated independently from the function of the main processor 121. The DDI 230 may communicate, for example, with touch circuitry 250 or the sensor module 176 via the interface module 231. The DDI 230 may also store at least part of the received image information in the memory 233, for example, on a frame by frame basis.

The image processing module 235 may perform pre-processing or post-processing (e.g., adjustment of resolution, brightness, or size) with respect to at least part of the image data. According to an embodiment, the pre-processing or post-processing may be performed, for example, based at least in part on one or more characteristics of the image data or one or more characteristics of the display 210.

The mapping module 237 may generate a voltage value or a current value corresponding to the image data pre-processed or post-processed by the image processing module 235. According to an embodiment, the generating of the voltage value or current value may be performed, for example, based at least in part on one or more attributes of the pixels (e.g., an array, such as an RGB stripe or a pentile structure, of the pixels, or the size of each subpixel). At least some pixels of the display 210 may be driven, for example, based at least in part on the voltage value or the current value such that visual information (e.g., a text, an image, or an icon) corresponding to the image data may be displayed via the display 210.

According to an embodiment, the display device 200 may further include the touch circuitry 250. The touch circuitry 250 may include a touch sensor 251 and a touch sensor IC 253 to control the touch sensor 251. The touch sensor IC 253 may control the touch sensor 251 to sense a touch input or a hovering input with respect to a certain position on the display 210. To achieve this, for example, the touch sensor 251 may detect (e.g., measure) a change in a signal (e.g., a voltage, a quantity of light, a resistance, or a quantity of one or more electric charges) corresponding to the certain position on the display 210. The touch circuitry 250 may provide input information (e.g., a position, an area, a pressure, or a time) indicative of the touch input or the hovering input detected via the touch sensor 251 to the processor 120. According to an embodiment, at least part (e.g., the touch sensor IC 253) of the touch circuitry 250 may be formed as part of the display 210 or the DDI 230, or as part of another component (e.g., the auxiliary processor 123) disposed outside the display device 200.

According to an embodiment, the display device 200 may further include at least one sensor (e.g., a fingerprint sensor, an iris sensor, a pressure sensor, or an illuminance sensor) of the sensor module 176 or a control circuit for the at least one sensor. In such a case, the at least one sensor or the control circuit for the at least one sensor may be embedded in one portion of a component (e.g., the display 210, the DDI 230, or the touch circuitry 150)) of the display device 200. For example, when the sensor module 176 embedded in the display device 200 includes a biometric sensor (e.g., a fingerprint sensor), the biometric sensor may obtain biometric information (e.g., a fingerprint image) corresponding to a touch input received via a portion of the display 210. As another example, when the sensor module 176 embedded in the display device 200 includes a pressure sensor, the pressure sensor may obtain pressure information corresponding to a touch input received via a partial or whole area of the display 210. According to an embodiment, the touch sensor 251 or the sensor module 176 may be disposed between pixels in a pixel layer of the display 210, or over or under the pixel layer.

The displays of various embodiments described below with reference to the drawings may be applied to (or included in) electronic devices having various form factors (e.g., the electronic device 101 in FIG. 1 or the display device 200 in FIG. 2). For example, the displays may be applied to, but are not limited to, portable communication devices (e.g., laptops, notebooks, or tablets), computer devices (e.g., desktops), or display devices (e.g., televisions, multi-vision displays, video wall displays, or digital signage) providing large-area screens.

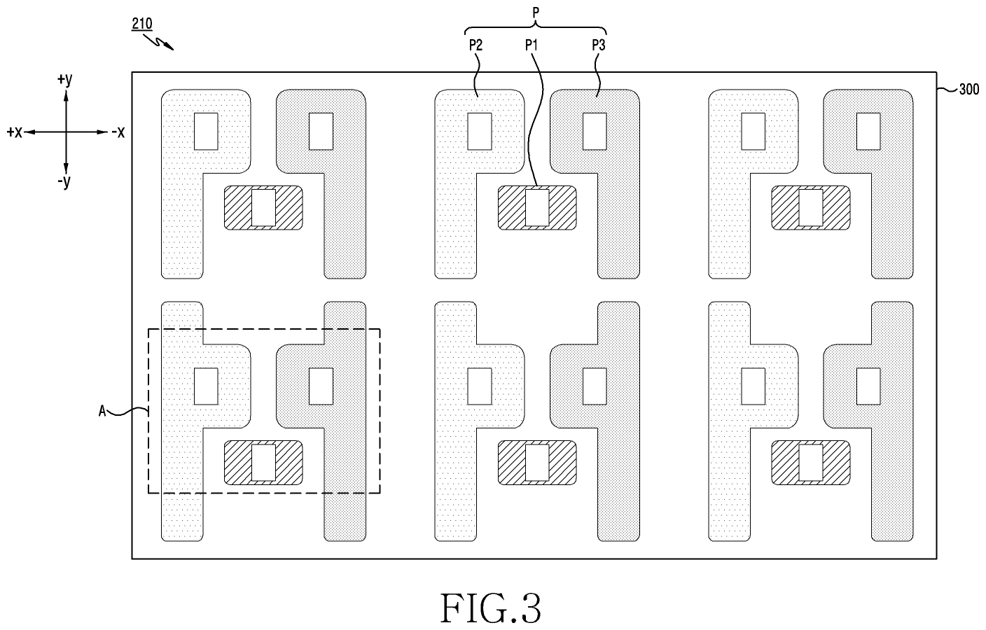

FIG. 3 is a plan view illustrating multiple pixels of a display according to an embodiment. As used herein, the “plan view” is a view in a thickness direction (i.e., third direction: e.g., the +Z and −Z directions) of the display 210.

Referring to FIG. 3, a display 210 according to an embodiment may include multiple pixels P in a display area for displaying an image. For example, the display 210 may include multiple pixels P arranged at predetermined intervals for each of a first direction (e.g., the +Y and −Y directions) and a second direction (e.g., the +X and −X directions) perpendicular to the first direction. In various embodiments, the multiple pixels P may be, but not exclusively, arranged in a pattern of a Bayer matrix, a pentile matrix, or a diamond matrix.

In an embodiment, multiple pixels P may be combined in a predetermined number (e.g., six) to form one pixel module 300. For example, the display 210 may include multiple assembled pixel modules 300 depending on the area of a screen to be provided by the display 210.

In an embodiment, each of the multiple pixels P may include multiple sub-pixels P1, P2, and P3 expressing different colors. For example, one pixel P may be composed of three sub-pixels P1, P2, and P3. Alternatively, at least some of the multiple pixels P may be composed of four or more sub-pixels.

In an embodiment, the multiple sub-pixels P1, P2, and P3 may express three primary colors. For example, among the multiple sub-pixels P1, P2, and P3, a first sub-pixel P1 may express blue, a second sub-pixel P2 may express red, and a third sub-pixel P3 may express green. Alternatively, the multiple sub-pixels P1, P2, and P3 may express a color formed by a combination of the three primary colors. For example, the multiple sub-pixels P1, P2, and P3 may express a color resulting from the combination of the blue of the first sub-pixel P1, the red of the second sub-pixel P2, and the green of the third sub-pixel P3.

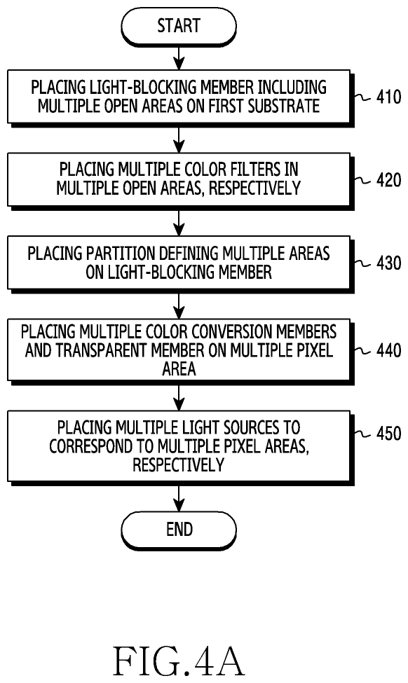

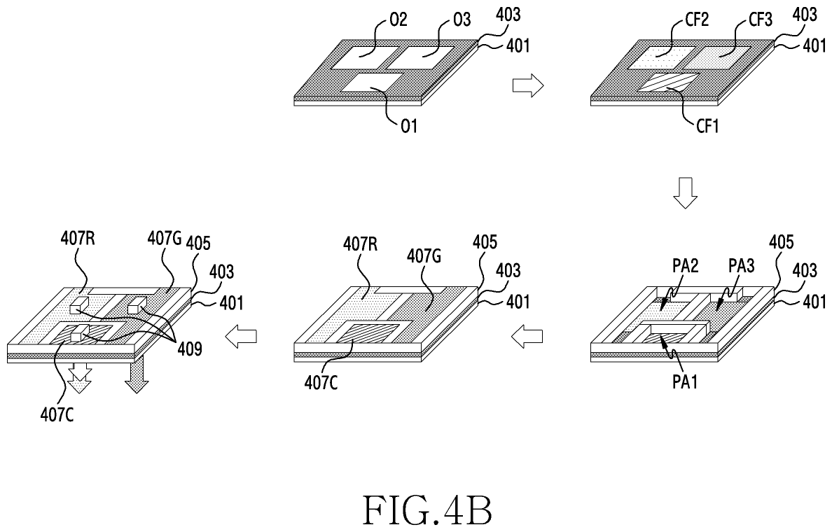

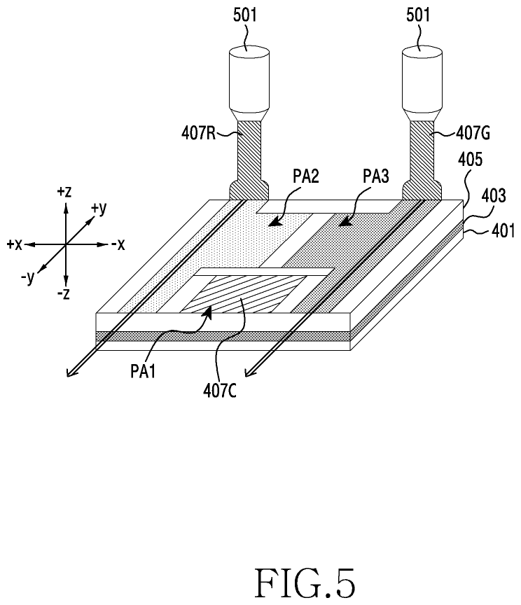

FIG. 4A is a view illustrating a method of manufacturing a display according to an embodiment. FIG. 4B is a view illustrating a process of manufacturing the display according to an embodiment. FIG. 5 is a view illustrating a process of printing a color conversion member according to an embodiment.

Hereinafter, in describing the embodiment illustrated in FIG. 4A, the embodiments of FIGS. 4B and 5 may be referenced together. Operations in the method and process of manufacturing a display (e.g., the display 210 in FIG. 3) mentioned in the embodiments of FIGS. 4A and 4B may be performed sequentially, but are not necessarily performed sequentially. For example, the order of the process steps in the method and process of manufacturing the display 210 mentioned in the embodiments of FIGS. 4A and 4B may be changed, or at least two manufacturing process steps may be performed in parallel.

The embodiments described with reference to FIGS. 4B and 5 may be referred to as a manufacturing process and a printing process for a portion of a display 210 (e.g., an area A including one pixel in FIG. 3). However, the display 210 includes a pixel module in which multiple pixels are combined (e.g., the pixel module 300 in FIG. 3). From this perspective, the embodiments described with reference to FIGS. 4A, 4B, and 5 may also be equally applied to other areas of the display 210 (e.g., areas other than the area A in FIG. 3).

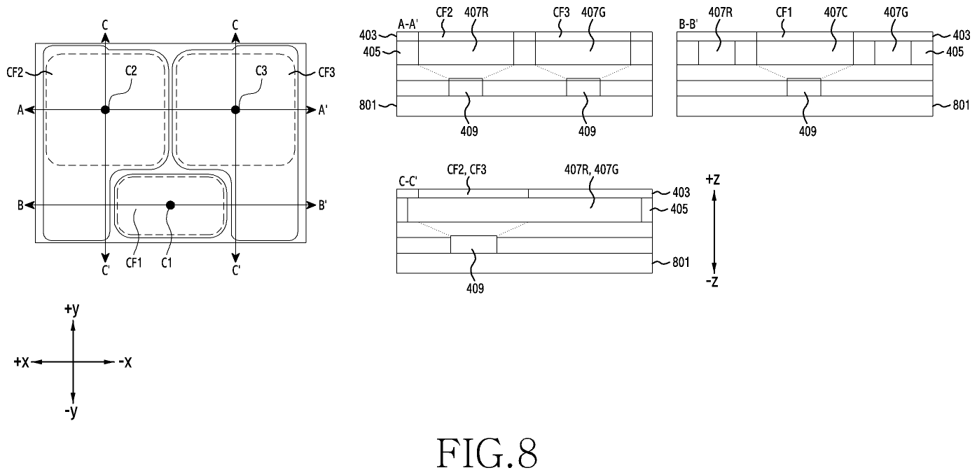

Referring to FIGS. 4A and 4B, the display 210 according to an embodiment may be manufactured to include a light-blocking member 403, multiple color filters CF1, CF2, and CF3, a partition 405, color conversion members 407R and 407G, a transparent member 407C, and multiple light sources 409. In various embodiments, the display (210) may be manufactured such that at least some of the above-described components are omitted or other additional components are further included. For example, the display 210 may further include a first substrate 401 on which the light-blocking member 403 is placed and a second substrate 801 (See FIG. 8) on which the multiple light sources 409 are placed.

Regarding the method of manufacturing the display 210 according to an embodiment, in operation 410, the light-blocking member 403 may be placed on the first substrate 401 (e.g., a glass substrate). According to an embodiment, the light-blocking member 403 may include multiple open areas O1, O2, and O3 where color filters CF1, CF2, and CF3 are placed, respectively. The areas (e.g., light-blocking member 403) other than the multiple open areas O1, O2, and O3 may block light incident on the first substrate 401. In an embodiment, in a portion of the display 210 (e.g., area A including a single pixel in FIG. 3), the light-blocking member 403 may include a first open area O1 with a first size and multiple second open areas O2 and O3 with a second size. For example, each of the multiple second open areas O2 and O3 may be the same second size, which may be larger than the first size of the first open area O1.

According to an embodiment, in operation 420, multiple color filters CF1, CF2, and CF3 may be placed in the open areas O1, O2, and O3 of the light-blocking member 403, respectively. For example, among the multiple open areas O1, O2, and O3, a blue first color filter CF1 may be placed in the first open area O1, and multiple second color filters CF2 and CF3 may be placed in the second open areas O2 and O3, respectively. In an embodiment, the multiple second color filters CF2 and CF3 may include a red color filter CF2 and a green color filter CF3. For instance, the color filters CF2 and CF3 may be placed in the multiple second open areas O2 and O3, respectively, in a sequential order of red and green, or in a sequential order of green and red.

In an embodiment, the multiple color filters CF1, CF2, and CF3 may have sizes corresponding to the open areas of the light-blocking member 403 in which the color filters are placed, respectively. For example, the first color filter CF1 placed in the first open area O1 may have a first size corresponding to (or substantially the same as) the first size of the first open area O1. Similarly, the multiple second color filters CF2 and CF3 placed in the second open areas O2 and O3, respectively, may each have a second size corresponding to (or substantially the same as) the second size of each of the multiple second open areas O2 and O3. Based on this, the sizes of the multiple second color filters CF2 and CF3 placed in the second open areas O2 and O3, respective, may each be larger than the size of the first color filter CF1 placed in the first open area O1. In an embodiment, the combination of the light-blocking member 403 and the multiple color filters CF1, CF2, and CF3 placed in the multiple open areas O1, O2, and O3 of the light-blocking member 403 may be referred to as a light-blocking layer or a color filter layer.

According to an embodiment, in operation 430, a partition 405 may be placed on the light-blocking member 403. In an alternative embodiment, a flattening layer (not illustrated) for flattening a step between the multiple color filters CF1, CF2, and CF3, and the light-blocking member 403 may be placed on the light-blocking member 403, and the partition 405 may be placed on the flattening layer.

In an embodiment, the partition 405 may form (or define) multiple pixel areas PA1, PA2, and PA3. For example, the partition 405 may be formed to surround a first color filter CF1 placed in the first open area O1 to define a first pixel area PA1, and may be formed to surround multiple second color filters CF2 and CF3 placed in the multiple second open areas O1 and O2, respectively, to define the multiple second pixel areas PA2 and PA3, respectively. In an embodiment, the partition 405 may be made of a light-blocking or light-reflecting material.

In an embodiment, the multiple pixel areas PA1, PA2, and PA3 formed (or defined) by the partition 405 may correspond to the multiple sub-pixels (e.g., the multiple sub-pixels P1, P2, and P3 in FIG. 3) included in a pixel (e.g., the pixel P in FIG. 3), respectively. For example, the first pixel area PA1 may correspond to the first sub-pixel P1 expressing blue, and the multiple second pixel areas PA2 and PA3 may correspond to the second sub-pixel P2 expressing red and the third sub-pixel P3 expressing green, respectively.

According to an embodiment, the depth of each of the multiple pixel areas PA1, PA2, and PA3 formed (or defined) by the partition 405 may be the same. For example, the height of the partition 405 forming the first pixel area PA1 and the height of the partition 405 forming each of the multiple second pixel areas PA2 and PA3 may be the same.

In an embodiment, the multiple second pixel areas PA2 and PA3 may have the same volume as each other and may have a volume different from a volume of the first pixel area PA1. For example, the volume of each of the multiple second pixel areas PA2 and PA3 may be larger than the volume of the first pixel area PA1. In an embodiment, each of the multiple pixel areas PA1, PA2, and PA3 may share at least a portion of the partition 405 with the adjacent pixel areas.

According to an embodiment, in operation 440, color conversion members 407R and 407G may be placed in some of the multiple pixel areas PA1, PA2, and PA3 formed (or defined) by the partition 405. In addition, members having different characteristics (e.g., transparent member 407C) from the color conversion members 407R and 407G may be placed in other ones of the multiple pixel areas PA1, PA2, and PA3 where the color conversion members 407R and 407G are not placed.

Referring to FIG. 5, the color conversion members 407R and 407G may be printed, based on an electrohydrodynamic (“EHD”) spinning process, on the multiple second pixel areas PA2 and PA3 defined by the partition 405, respectively. For example, ink including a red quantum dot or a red fluorescent material injected from a nozzle 501 may be applied to one of the multiple second pixel areas PA2 and PA3 (e.g., the pixel area PA2), and then cured to form a color conversion member 407R that converts light energy incident on the corresponding pixel area PA2 to the red light. Similarly, ink including a green quantum dot or a green fluorescent material injected from the nozzle 501 may be applied to another one of the multiple second pixel areas PA2 and PA3 (e.g., the pixel area PA3), and then cured to form a color conversion member 407G that converts light energy incident on the corresponding pixel area PA2 to the green light. According to an embodiment, in the EHD spinning process, the nozzle 501 may move in a first direction (e.g., the +Y and −Y directions), and the ink ejected from the nozzle 501 may flow (e.g., flow in the second direction (the +X and −X directions)) inside the multiple second pixel areas PA2 and PA3 by the partition 405 before being cured, and be filled in the multiple second pixel areas PA2 and PA3. In an embodiment, a transparent member 407C may be formed in the first pixel area PA1 based on a photo-lithography process. For example, an optically transparent member 407C (e.g., resin) may be formed in the first pixel area PA1. In an embodiment, a combination of the partition 405, the transparent member 407C placed in the first pixel area PA1 of the partition 405, and the color conversion members 407R and 407G placed in the second pixel areas PA2 and PA3 of the partition 405, respective, may be referred to as a partition layer or a color conversion layer.

According to an embodiment, in operation 450, multiple light sources 409 may be placed on the multiple pixel areas PA1, PA2, and PA3 defined by the partition 405, respectively. For example, the multiple light sources 409 may be placed on the color conversion members 407R and 407G and the transparent member 407C formed in the multiple pixel areas PA1, PA2, and PA3, respectively, so as to be aligned with the multiple color filters CF1, CF2, and CF3 corresponding to the multiple pixel areas PA1, PA2, and PA3, respectively. In an alternative embodiment, the multiple light sources 409 may be placed on a second substrate (e.g., a thin film transistor (TFT) circuit substrate) for driving the multiple light sources 409, and the second substrate may be placed on the partition layer or the color conversion layer using an optically transparent adhesive member. In an embodiment, the multiple light sources 409 may include organic light emitting diodes (OLEDs) and/or micro LEDs that provide light in a blue wavelength band.

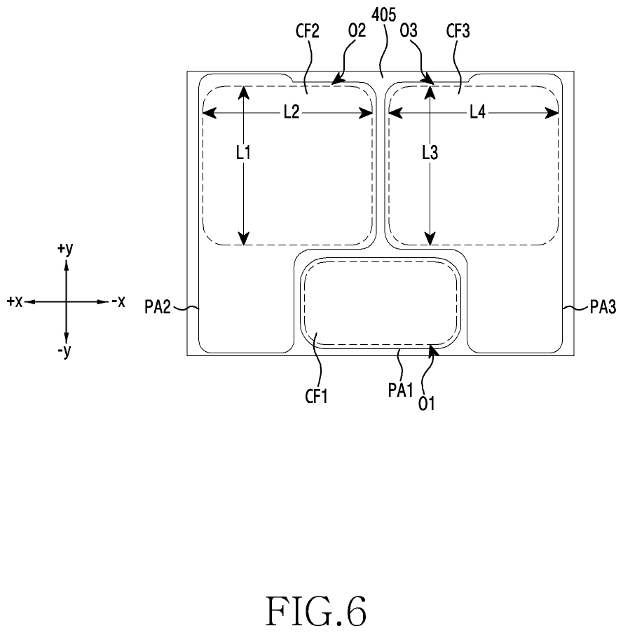

FIG. 6 is a plan view illustrating a portion of a display according to an embodiment.

In the embodiment of FIG. 6, the portion of the display may be referred to as area A including one pixel of the display (e.g., the display 210) illustrated in FIG. 3.

Referring to FIG. 6, the size of each of the multiple second color filters CF2 and CF3 included in the display 210 according to an embodiment and the size of the first color filter CF1 may be different. For example, the first open area O1 of the light-blocking member (e.g., the light-blocking member 403 in FIG. 4B) may have a first size, and the first color filter CF1 placed in the first open area O1 may have a first size corresponding to (or substantially identical to) the above first size. In addition, for example, the multiple second open areas O2 and O3 of the light-blocking member 403 may each have a second size larger than the first size, and the multiple second color filters CF2 and CF3 placed in the multiple second open areas O2 and O3, respectively, may each have a second size corresponding to the above second size.

In an embodiment, the areas/sizes of the multiple pixel areas PA1, PA2, and PA3 formed (or defined) by the partition 405 may be at least partially different. For example, in a plan view, the size of a first pixel area PA1 may have a first size corresponding to (or substantially identical to) the first size of the first open area O1 or the first color filter CF1. In addition, for example, in a plan view, the size of each of the multiple second pixel areas PA2 and PA3 may have a third size greater than the second size of each of the multiple second open areas O2 and O3 or the multiple second color filters CF2 and CF3. In an embodiment, of the size of each of the multiple second pixel areas PA2 and PA3 having the third size, in the area that does not correspond to the multiple second open areas O2 and O3 or the multiple second color filters CF2 and CF3 having the second size, a light-blocking member 403 may be positioned in a plan view. In contrast, the size of the first pixel area PA1 having the first size may be occupied by the first open area O1 or the first color filter CF1 having the same first size, so that the light-blocking member 403 may not be positioned.

In an embodiment, each of the multiple second open areas O2 and O3 may have a first length L1 or L3 in the first direction (e.g., the +Y and −Y directions) and a second length L2 or L4 in the second direction (e.g., the +X and −X directions) perpendicular to the first direction, which may differ from each other. For example, the first length L1 or L3 of each of the multiple second open areas O2 and O3 may be greater than the second length L2 or L4.

According to an embodiment, the first pixel area PA1 may be positioned between the multiple second pixel areas PA2 and PA3. For instance, the partition 405 may form (or define) the multiple second pixel areas PA2 and PA3 with symmetrical shapes with respect to a virtual line parallel to the first direction (e.g., the +Y and −Y directions) and disposed between the second pixel area PA2 and the second pixel area PA3, and the first pixel area PA1 may be formed in the intermediate area defined by the symmetrical shapes of the multiple second pixel areas PA2 and PA3.

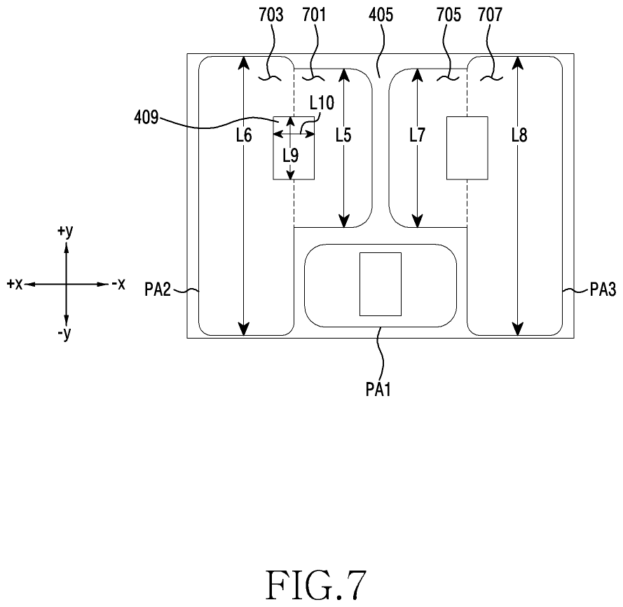

FIG. 7 is a plan view illustrating the second pixel area and the third pixel area of a portion of the display according to an embodiment.

In the embodiment of FIG. 7, the portion of the display may be referred to as area A including one pixel of the display (e.g., the display 210) illustrated in FIG. 3. Referring to FIG. 7, each of the multiple second pixel areas PA2 and PA3 included in the display 210 according to an embodiment may include a first area 701 or 705 and a second area 703 or 707. For example, the first area 701 or 705 and the second area 703 or 707 of each of the multiple second pixel areas PA2 and PA3 are areas distinguished by their shapes, and may open to each other in the second direction (e.g., the +X and −X directions) without being physically blocked by the partition 405.

In an embodiment, the first area 701 or 705 of each of the multiple second pixel areas PA2 and PA3 may have a first length L5 or L7 in the first direction (e.g., the +Y and −Y directions), while the second area 703 or 707 of each of the multiple second pixel areas PA2 and PA3 may have a second length L6 or L8 in the first direction, which is greater than the first length L5 or L7. In various embodiments, the first area 701 or 705 and the second area 703 or 707 may have either the same length or different lengths in the second direction (e.g., the +X and −X directions), which is perpendicular to the first direction.

In an embodiment, the first area 701 or 705 of each of the multiple second pixel areas PA2 and PA3 may be formed to protrude from the second area 703 or 707 of the corresponding second pixel area PA2 or PA3 toward the adjacent second pixel area PA3 or PA2. For example, the first area 701 of the second pixel area PA2 may be formed to protrude in the second direction (e.g., the −X direction) from the second area 703 to the second pixel area PA3, and the first area 705 of the second pixel area PA3 may be formed to protrude in the second direction (e.g., the +X direction) from the second area 707 to the second pixel area PA2. Based on this, each of the multiple second pixel areas PA2 and PA3 may have a “P” shape, and the first area 701 or 705 of each of the multiple second pixel areas PA2 and PA3 may overlap at least a portion of the first pixel area PA1 in the first direction (e.g., the +Y and −Y directions). The first areas 701 and 705 of the multiple second pixel areas PA2 and PA3 may not overlap the first pixel area PA1 in the second direction (e.g., the +X and −X directions), while parts (e.g., first parts) of the second areas 703 and 707 may overlap the first pixel area PA1 in the second direction. The first pixel area PA1 may be located in a space formed by the first areas 701 and 705 and the second areas 703 and 707.

In an embodiment, the multiple light sources 409 arranged in each of the multiple pixel areas PA1, PA2, and PA3 may have their longitudinal directions corresponding to the first direction (e.g., the +Y and −Y directions). For example, the first length L9 of each of the multiple light sources 409 in the first direction (e.g., the +Y and −Y directions) may be greater than the second length L10 of each of the multiple light sources 409 in the second direction (e.g., the +X and −X directions) perpendicular to the first direction.

Referring to FIGS. 6 and 7, in a plan view, the second color filter CF2 may overlap the first area 701 and another part (e.g., second part) of the second area 703 overlapping the first area 701 in the second direction, and the second color filter CF3 may overlap the first area 705 and another part (e.g., second part) of the second area 707 overlapping the first area 705 in the second direction. In a plan view, the parts (e.g., first parts) of the second areas 703 and 707 overlapping the first pixel area PA1 in the second direction may not overlap the multiple second color filters CF2 and CF3.

In an embodiment, the sizes and shapes of the color conversion members 407R and 407G may be the same as the sizes and shapes of the multiple second pixel areas PA2 and PA3, respectively, in a plan view, and the size and shape of the transparent member 407C may be the same as the size and shape of the first pixel area PA1 in a plan view. Therefore, the descriptions above regarding the sizes and shapes of the multiple second pixel areas PA2 and PA3 and the first pixel area PA1 may be applied to the sizes and shapes of the color conversion members 407R and 407G and the transparent member 407C, respectively.

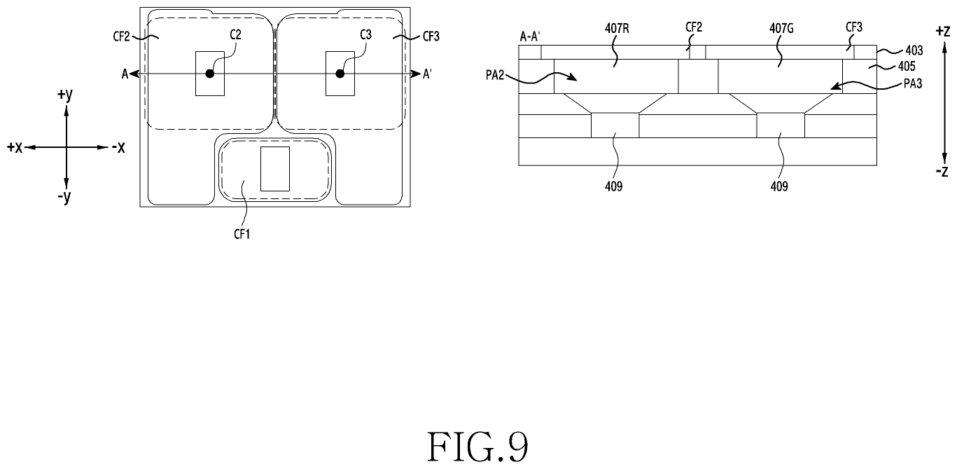

FIG. 8 is a view illustrating cross-sections of a portion of a display according to one embodiment in various directions. FIG. 9 is a view illustrating a cross-section of a portion of a display according to another embodiment in one direction.

In the embodiments of FIGS. 8 and 9, a portion of the display may be referred to as area A, which includes a single pixel of the display (e.g., the display 210) illustrated in FIG. 3.

Referring to FIG. 8, the centers of the multiple second color filters CF2 and CF3 included in the display 210 according to an embodiment may be positioned on the same line (e.g., line A-A′). For example, the centers C2 and C3 of the multiple second color filters CF2 and CF3, respective, may be positioned on a first line (e.g., line A-A′) extending in the second direction (e.g., the +X and −X directions). In an embodiment, the center C1 of the first color filter CF1 may be positioned on a second line (e.g., line B-B′) that is different from and parallel to the first line (e.g., line A-A′). In an embodiment, the multiple color filters CF1, CF2, and CF3 may not overlap each other in a plan view. Based on this, in the cross-section of the display 210 taken along the first line (e.g., line A-A′), multiple second color filters CF2 and CF3 having the second size, multiple second pixel areas (e.g., the multiple second pixel areas PA2 and PA3 in FIG. 7) in which the multiple second color filters CF2 and CF3 are placed, respectively, color conversion members 407R and 407G within the multiple second pixel areas PA2 and PA3, and multiple light sources 409 corresponding to the multiple second pixel areas PA2 and PA3, respective, may be positioned. In the cross-section of the display 210 taken along the second line (e.g., line B-B′), a first color filter CF1 having a first size smaller than the second size, a transparent member 407C within the first pixel area (e.g., the first pixel area PA1 in FIG. 7) where the first color filter CF1 is placed, the color conversion members 407R and 407G, and a light source 409 corresponding to the first pixel area PA1 may be positioned. In the cross-section of the display 210 taken along the third line (e.g., line C-C′) in the first direction (e.g., the +Y and −Y directions) where the center (C2 or C3) of one of the multiple second color filters CF2 and CF3 is positioned, the second color filter CF2 or CF3 having the second size, a color conversion member 407R or 407G within the second pixel area PA2 or PA3 where the second color filter is placed, and a light source 409 corresponding to the second pixel area PA2 or PA3 may be positioned.

According to various examples, a portion of the blue wavelength band light provided by the multiple light sources 409 corresponding to the multiple second pixel areas PA2 and PA3, respectively, may be absorbed by the partition 405 forming (or defining) the multiple second pixel areas PA2 and PA3, and dissipated as heat, or may be absorbed by the color conversion members 407R and 407G placed in the multiple second pixel areas PA2 and PA3, and dissipated as heat. That is, when the color conversion members 407R and 407G placed in the multiple second pixel areas PA2 and PA3 have the same size or volume as the transparent member 407C placed in the first pixel area PA1, the second pixel (e.g., the second sub-pixel P2 in FIG. 3) and the third pixel (e.g., the third sub-pixel P3 in FIG. 3) corresponding to the multiple second pixel areas PA2 and PA3, respectively, may exhibit reduced optical efficiency compared to the first pixel (e.g., the first sub-pixel P1 in FIG. 3) corresponding to the first pixel area PA1. In addition, when the multiple second color filters CF2 and CF3 corresponding to the multiple second pixel areas PA2 and PA3, respectively, each have the same size as the first color filter CF1 corresponding to the first pixel area PA1, the second sub-pixel P2 and the third sub-pixel P3 corresponding to the multiple second pixel areas PA2 and PA3, respectively, may exhibit reduced optical efficiency compared to the first sub-pixel P1 corresponding to the first pixel area PA1, since the multiple light sources 409 provide blue wavelength band light.

In contrast, the display 210 according to an embodiment may compensate for the light energy dissipated in the partition 405 and/or the color conversion members 407R and 407G by increasing the amount of blue wavelength band light incident on the color conversion members 407R and 407G, based on the structure where the size or volume of the color conversion members 407R and 407G (or the multiple second pixel areas PA2 and PA3 where the color conversion members 407R and 407G are placed) is increased compared to the transparent member 407C (or the first pixel area PA1 where the transparent member 407C is placed). In addition, the display 210 according to an embodiment may compensate for the light energy dissipated in the partition 405 and/or the color conversion members 407R and 407G by increasing the amount of color-converted light (e.g., red or green light) incident on the multiple second color filters CF2 and CF3, based on the structure in which the size of the multiple second color filters CF2 and CF3, which receive light color-converted by the color conversion members 407R and 407G, is increased compared to the first color filter CF1, which receives blue light transmitted through the transparent member 407C.

Referring to FIG. 9, the multiple color filters CF2 and CF3 corresponding to the multiple second pixel areas (e.g., the multiple second pixel areas PA2 and PA3 in FIG. 7), respectively, included in the display 210 according to an embodiment may each have a second size larger than the first size of the first color filter CF1 corresponding to the first pixel area (e.g., the first pixel area PA1 in FIG. 7). According to an embodiment, with reference to the first line (e.g., A-A′ line) in the second direction (e.g., the +X and −X directions) where the centers C2 and C3 of the multiple second color filters CF2 and CF3 are positioned, respectively, the length of the second size of each of the multiple second color filters CF2 and CF3 in the second direction may be greater than the length of each of the multiple second pixel areas PA2 and PA3 in the second direction. Based on this, in the cross-section of the display 210 taken along a first line (e.g., line A-A′ line), each of the multiple second color filters CF2 and CF3 may overlap at least a portion of the partition 405 forming (or defining) the multiple second pixel areas PA2 and PA3.

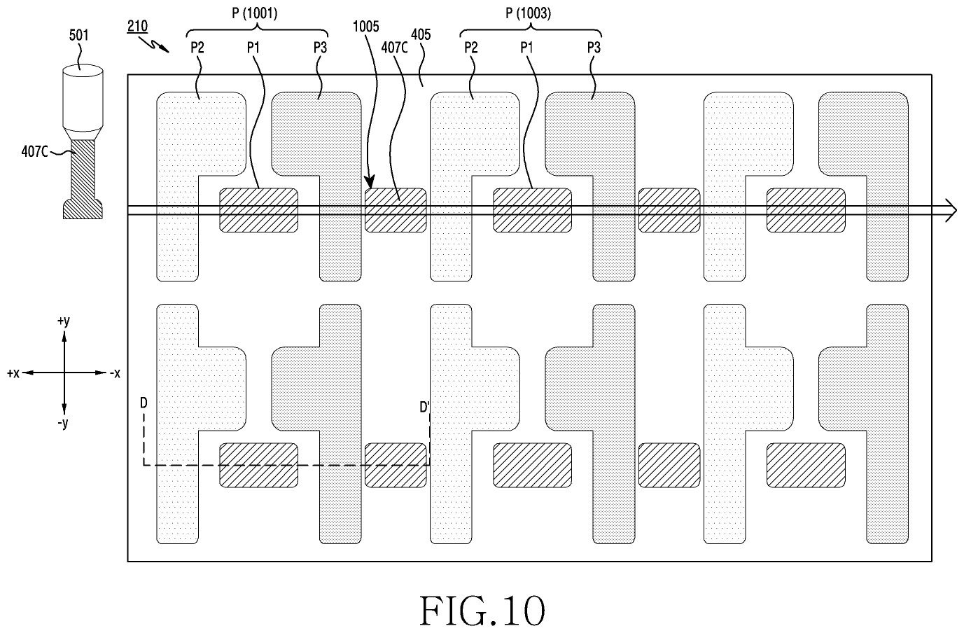

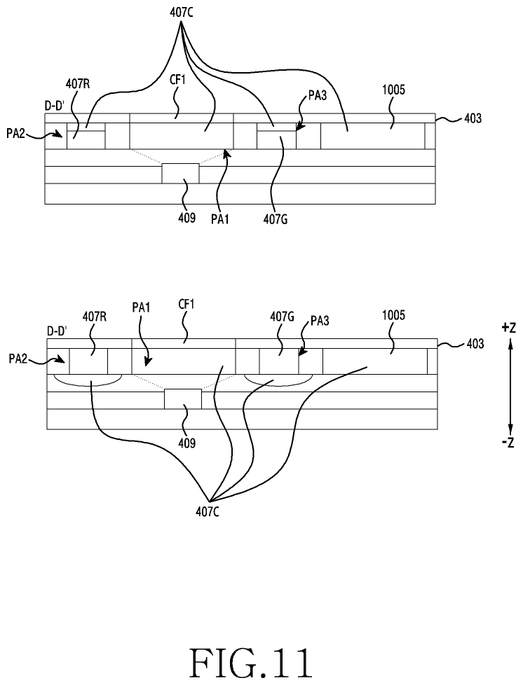

FIG. 10 is a plan view illustrating a process of printing a transparent member according to an embodiment. FIG. 11 is a view illustrating cross-sections of portions of a display according to an embodiment in one direction.

Referring to FIGS. 10 and 11, a display 210 according to an embodiment may include an empty space 1005 formed between adjacent sub-pixels of multiple pixels 1001 and 1003. For example, along the same line as a first sub-pixel P1 of each of the multiple pixels 1001 and 1003, an empty space 1005 may be formed in a partition 405 between adjacent sub-pixels (e.g., between the third sub-pixel P3 of the pixel 1001 and the second sub-pixel P2 of the pixel 1003) of the multiple pixels 1001 and 1003. According to an embodiment, during the process of printing a transparent member 407C onto the first pixel area PA1 corresponding to the first sub-pixel P1 of each of the multiple pixels 1001 and 1003, a transparent member 407C may also be printed in the empty space 1005. For example, in the structure of the display 210 including the empty spaces 1005, a transparent member 407C may be printed onto in first pixel area PA1 based on an EHD spinning process directed in the second direction (e.g., the +X and −X directions), and a transparent member 407C may also be printed in the empty space 1005 along the line corresponding to the first pixel area PA1 based on the same EHD spinning process.

In an embodiment, as shown in the upper figure of FIG. 11, after printing the transparent members 407C onto the first pixel area PA1 corresponding to the first sub-pixel P1 and the empty space 1005 using the EHD spinning process directed in the second direction (e.g., the +X and −X directions), when the color conversion members 407R and 407G are printed onto the multiple second pixel areas PA2 and PA3 corresponding to the second sub-pixel P2 and the third sub-pixel P3, respectively, using the EHD spinning process directed in the first direction (e.g., the +Y and −Y directions) perpendicular to the second direction, within each of the multiple second pixel areas PA2 and PA3, the transparent member 407C may be positioned between the light-blocking member 403 and the color conversion member 407R or 407G. Conversely, in another embodiment, as shown in the lower figure of FIG. 11, after printing the color conversion members 407R and 407G onto the multiple second pixel areas PA2 and PA3 corresponding to the multiple second sub-pixels P2 and P3, respectively, using an EHD spinning process directed in the first direction (e.g., the +Y and −Y directions), when the transparent member 407C is printed onto the first pixel areas PA1 corresponding to the first sub-pixel P1 and the empty space 1005 using the EHD spinning process directed in the second direction (e.g., the +X and −X directions), in each of the multiple second pixel areas PA2 and PA3, the transparent member 407C may be positioned to cover at least a portion of the partition 405 forming the corresponding second pixel area PA2 or PA3 and at least a portion of the color conversion member 407R or 407G printed onto the corresponding second pixel area PA2 or PA3.

According to various embodiments, the empty space 1005 may be connected to the first pixel area PA1 corresponding to the first sub-pixel P1 of each of the multiple pixels 1001 and 1003. In such cases, the first pixel area PA1 corresponding to the first sub-pixel P1 of each of the multiple pixels 1001 and 1003 may extend in the second direction (e.g., the +X and −X directions) without being separated by the partition 405.

According to an embodiment of the disclosure, a display 210 may include multiple light sources 409, a partition 405 defining multiple pixel areas PA1, PA2, and PA3 corresponding to the multiple light sources, respectively, color conversion members 407R and 407G disposed in some of the multiple pixel areas, a transparent member 407C disposed in another some of the multiple pixel areas; a light-blocking member 403 including multiple open areas O1, O2, and O3 corresponding to the multiple pixel areas, respectively, and multiple color filters CF1, CF2, and CF3 placed in the multiple open areas, respectively. The multiple color filters may include a first color filter CF1 having a first size and multiple second color filters CF2 and CF3 each having a second size larger than the first size, and the first color filter CF1 may overlap the transparent member 407C in the plan view, and the multiple second color filters CF2 and CF3 may overlap the color conversion members 407R and 407G in the plan view.

According to an embodiment of the disclosure, the first color filter may include a blue color filter, and the multiple second color filters may include a red color filter and a green color filter.

According to an embodiment of the disclosure, the multiple open areas may include a first open area O1 where the first color filter is placed and multiple second open areas O2 and O3 where the multiple second color filters are placed, respectively, the first open area may have the first size, and each of the multiple second open areas may have the second size, which is larger than the first size.

According to an embodiment of the disclosure, the multiple pixel areas may include a first pixel area PA1 corresponding to the first color filter and multiple of second pixel areas PA2 and PA3 which correspond to the multiple second color filters, respectively, the size of the first pixel area in the plan view may have a first size, and the size of each of the multiple second pixel areas may have a third size larger than the second size in a plan view.

According to an embodiment of the disclosure, the first pixel area may be positioned between the multiple second pixel areas.

According to an embodiment of the disclosure, the multiple second pixel areas may have symmetrical shapes with respect to a virtual line between the multiple second pixel areas.

According to an embodiment of the disclosure, each of the multiple second pixel areas may include a first area 701 or 705 and a second area 703 or 707, the first area may have a first length in a first direction, and the second area may have a second length in the first direction, where the second length is greater than the first length.

According to an embodiment of the disclosure, the first area may protrude from the second area in a second direction perpendicular to the first direction.

According to an embodiment of the disclosure, the first area may overlap at least a portion of the first pixel area in the first direction.

According to an embodiment of the disclosure, each of the multiple light sources may have a first length in the first direction and a second length in the second direction perpendicular to the first direction, where the second length is smaller than the first length.

According to an embodiment of the disclosure, the multiple second color filters may overlap at least a portion of the partition in the plan view.

According to an embodiment of the disclosure, a center of the first color filter CF1 among the multiple color filters CF1, CF2 and CF3 is disposed on a first virtual line, and centers of the multiple second color filters CF2 and CF3 among the multiple color filters CF1, CF2 and CF3 are positioned on a second virtual line that is parallel to the first virtual line.

According to an embodiment of the disclosure, a display 210 may include multiple light sources 409, a partition 405 defining multiple pixel areas PA1, PA2, and PA3 corresponding to the multiple light sources, respectively, multiple color conversion members 407R and 407G disposed in some of the multiple pixel areas, a transparent member 407C disposed in another some of the multiple pixel areas; a light-blocking member 403 including multiple open areas O1, O2, and O3 corresponding to the multiple pixel areas, respectively, and multiple color filters CF1, CF2, and CF3 placed in the multiple open areas, respectively. The multiple color conversion members 407R and 407G may each have a first size in a plan view, and the transparent member 407C may have a second size smaller than the first size in a plan view. The multiple color filters CF1, CF2, and CF3 may include a first color filter CF1 overlapping the transparent member 407C in the plan view and multiple second color filters CF2, and CF3 overlapping the multiple color conversion members 407R and 407G in the plan view.

According to an embodiment of the disclosure, a center of the first color filter CF1 among the multiple color filters CF1, CF2 and CF3 is disposed on a first virtual line, and centers of the multiple second color filters CF2 and CF3 among the multiple color filters CF1, CF2 and CF3 are positioned on a second virtual line that is parallel to the first virtual line.

According to an embodiment of the disclosure, the first color filter may include a blue color filter, and the multiple second color filters may include a red color filter and a green color filter.

According to an embodiment of the disclosure, the multiple open areas may include a first open area O1 where the first color filter is placed and multiple second open areas O2 and O3 where the multiple second color filters are placed, respectively, the first open area may have a third size, and each of the multiple second open areas may have a fourth size, which is larger than the third size.

According to an embodiment of the disclosure, the multiple pixel areas may include a first pixel area PA1 corresponding to the first color filter and multiple of second pixel areas PA2 and PA3 which correspond to the multiple second color filters, respectively, the size of the first pixel area in the plan view may have the third size, and the size of each of the multiple second pixel areas in the plan view may have a fifth size larger than the fourth size in a plan view.

According to an embodiment of the disclosure, the first pixel area may be positioned between the multiple second pixel areas, and the multiple second pixel areas may have symmetrical shapes with respect to a virtual line between the multiple second pixel areas.

According to an embodiment of the disclosure, each of the multiple second pixel areas may include a first area 701 or 705 and a second area 703 or 707, the first area may have a first length in a first direction, and the second area may have a second length in the first direction, where the second length is greater than the first length.

According to an embodiment of the disclosure, the first area may protrude from the second area in a second direction perpendicular to the first direction.

According to an embodiment of the disclosure, a method of manufacturing a display may include operation 410 of placing a light-blocking member 403 including multiple of open areas O1, O2, and O3 on a first substrate 401, operation 420 of placing multiple color filters CF1, CF2, and CF3 in the multiple open areas, respectively, operation 430 of placing a partitions 405 defining multiple pixel areas PA1, PA2, and PA3 on the light-blocking member, operation 440 of placing color conversion members 407R and 407G and transparent member 407C in the multiple pixel areas, and operation 450 of placing multiple light sources 409 to correspond the multiple pixel areas, respectively. The operation of placing the multiple color filters may include placing a first color filter CF1 having a first size and multiple second color filters CF2 and CF3 each having a second size larger than the first size in a plan view. The first color filter CF1 may overlap the transparent member 407C in the plan view, and the multiple second color filters CF2 and CG3 may overlap the multiple color conversion members 407R and 407G, respectively, in the plan view.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStoreTM), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. A display comprising:
multiple light sources;
a partition defining multiple pixel areas corresponding to the multiple light sources, respectively;
a color conversion member disposed in some of the multiple pixel areas;
a transparent member disposed in another some of the multiple pixel areas;
a light-blocking member including multiple open areas corresponding to the multiple pixel areas, respectively; and
multiple color filters placed in the multiple open areas, respectively,
wherein the multiple color filters include a first color filter having a first size and multiple second color filters each having a second size larger than the first size in a plan view,
wherein the first color filter overlaps the transparent member in the plan view, and the multiple second color filters overlap the color conversion member in the plan view.

2. The display of claim 1, wherein the first color filter includes a blue color filter, and
wherein the multiple second color filters include a red color filter and a green color filter.

3. The display of claim 1, wherein the multiple open areas includes a first open area where the first color filter is placed and multiple second open areas where the multiple second color filters are placed, respectively,
wherein the first open area may have the first size, and
wherein each of the multiple second open areas has the second size larger than the first size.

4. The display of claim 1, wherein the multiple pixel areas include a first pixel area corresponding to the first color filter and multiple second pixel areas corresponding to the multiple second color filters, respectively,
wherein a size of the first pixel area in the plan view has the first size, and
wherein a size of each of the multiple second pixel areas in the plan view has a third size larger than the second size.

5. The display of claim 4, wherein the first pixel area is positioned between the multiple second pixel areas.

6. The display of claim 4, wherein the multiple second pixel areas have symmetrical shapes with respect to a virtual line, between the multiple second pixel areas, crossing the first pixel area.

7. The display of claim 4, wherein each of the multiple second pixel areas includes a first area and a second area,
wherein the first area has a first length in a first direction, and
wherein the second area has a second length in the first direction, which is greater than the first length.

8. The display of claim 7, wherein the first area protrudes from the second area in a second direction perpendicular to the first direction.

9. The display of claim 7, wherein the first area overlaps at least a portion of the first pixel area in the first direction.

10. The display of claim 1, wherein each of the multiple light sources has a first length in a first direction and a second length in a second direction perpendicular to the first direction, where the second length is smaller than the first length.

11. The display of claim 1, wherein the multiple second color filters overlap at least a portion of the partitions in the plan view.

12. The display of claim 1, wherein a center of the first color filter among the multiple color filters is disposed on a first virtual line, and centers of the multiple second color filters among the multiple color filters are positioned on a second virtual line that is parallel to the first virtual line.

13. A display comprising:
multiple light sources;
a partition defining multiple pixel areas corresponding to the multiple light sources, respectively;
multiple color conversion members disposed in some of the multiple pixel areas;
a transparent member disposed in another some of the multiple pixel areas;
a light-blocking member including multiple open areas corresponding to the multiple pixel areas, respectively; and
multiple color filters placed in the multiple open areas, respectively, wherein the multiple color conversion members each have a first size in a plan view, and the transparent member has a second size smaller than the first size in the plan view,
wherein the multiple color filters include a first color filter overlapping the transparent member in the plan view and multiple second color filters overlapping the multiple color conversion members in the plan view.

14. The display of claim 13, wherein the first color filter includes a blue color filter, and
wherein the multiple second color filters include a red color filter and a green color filter.

15. The display of claim 13, wherein the multiple open areas includes a first open area where the first color filter is placed and multiple second open areas where the multiple second color filters are placed, respectively,
wherein the first open area has a third size, and
wherein each of the multiple second open areas has a fourth size larger than the third size.

16. The display of claim 15, wherein the multiple pixel areas include a first pixel area corresponding to the first color filter and multiple second pixel areas corresponding to the multiple second color filters, respectively,
wherein a size of the first pixel area in the plan view has the third size, and
wherein a size of each of the multiple second pixel areas in the plan view has a fifth size larger than the fourth size.

17. The display of claim 16, wherein the first pixel area may be positioned between the multiple second pixel areas, and
wherein the multiple second pixel areas have symmetrical shapes with respect to a virtual line, between the multiple second pixel areas, the first pixel area.

18. The display of claim 16, wherein each of the multiple second pixel areas includes a first area and a second area,
wherein the first area has a first length in a first direction, and
wherein the second area has a second length in the first direction, which is greater than the first length.

19. The display of claim 18, wherein the first area protrudes from the second area in a second direction perpendicular to the first direction.

20. A method of manufacturing a display, comprising:
placing a light-blocking member including multiple open areas on a first substrate;
placing multiple color filters in the multiple open areas, respectively;
placing a partition defining multiple pixel areas on the light-blocking member;
placing multiple color conversion members and a transparent member in the multiple pixel areas; and
placing multiple light sources to correspond to the multiple pixel areas, respectively,
wherein the placing of the multiple color filters includes placing a first color filter having a first size and multiple second color filters each having a second size larger than the first size in a plan view,
wherein the first color filter overlaps the transparent member in the plan view, and the multiple second color filters overlap the multiple color conversion members, respectively, in the plan view.
